(19) United States
(12) Patent Application Publication
(10) Pub. No.: US 2026/0084957 A1
(43) Pub. Date: Mar. 26, 2026

(54) METHODS FOR POST-PROCESSING AND FOR HANDLING OF MEMS CHIPS

(71) Applicant: Carl Zeiss SMT GmbH, Oberkochen (DE)

(72) Inventors: David METZ, Westhausen (DE); Yanko SAROV, Aalen (DE); Fabian HAACKER, Aalen (DE); Johannes EISENMENGER, Ulm (DE)

(21) Appl. No.: 19/365,297

(22) Filed: Oct. 22, 2025

Related U.S. Application Data
(63) Continuation of application No. PCT/EP2024/054380, filed on Feb. 21, 2024.

(30) Foreign Application Priority Data
Apr. 27, 2023 (DE) 10 2023 203 941.9

(51) Int. Cl. B81C 1/00; B81B 7/04

(52) U.S. Cl. CPC B81C 1/00904; B81B 7/04; B81B 2201/042; B81C 2201/0105; B81C 2201/013; B81C 2201/053

(57) ABSTRACT

In a method of post-processing MEMS chips comprising MEMS structures arranged on a carrier material and having at least one projection region of projecting material protruding laterally beyond the region of the MEMS chip provided with MEMS structures, at least one projection region is removed by separating the projecting material from the carrier material of the MEMS chip. For handling MEMS chips without regions projecting beyond the MEMS structures arranged on a carrier material, for example after post-processing according to the disclosure has been carried out, at least one lateral depression is provided in the carrier material and the MEMS chips are handled by way of a tool engaging in the lateral depression(s).

### CROSS-REFERENCE TO RELATED APPLICATIONS

The present application is a continuation of, and claims benefit under 35 USC 120 to, international application No. PCT/EP2024/054380, filed Feb. 21, 2024, which claims benefit under 35 USC 119 of German Application No. 10 2023 203 941.9, filed Apr. 27, 2023. The entire disclosure of each of these applications is incorporated by reference herein.

### FIELD

The disclosure relates to a method for post-processing of MEMS chips and to a method for handling of MEMS chips.

### BACKGROUND

Microelectromechanical systems (MEMS) are small components that combine micromechanical structures and electronic elements in a single chip. MEMS chips can be produced in a manner comparable to microchips with integrated circuits. A MEMS chip comprises a carrier material, on which the actual MEMS structures are arranged.

In general, a plurality of MEMS chips are produced on a common wafer - comparable to microchips with integrated circuits. After the MEMS structures have been produced, the wafer is suitably divided so that individual MEMS chips are formed, which can then be used further and, for example, can be integrated into larger assemblies.

It is known to provide MEMS chips with a protective cover in order to protect the MEMS structures from environmental influences and mechanical damage, especially during further handling after the MEMS chips have been produced.

A known option is to apply a wafer provided with suitable depressions on the wafer provided with the MEMS structures so that the applied wafer bears against the carrier material of the MEMS chips and is fixedly connected to it in the regions between the groups of MEMS structures which are each assigned to a MEMS chip. When the wafers that have been connected in this way are divided to form individual MEMS chips, each MEMS chip is then provided with a protective cover that extends over the MEMS structures of the MEMS chip and protects them from environmental influences and mechanical damage.

In certain MEMS chips, for example those with optical functions, a protective cover can be provided in the course of production in order to simplify the handling of the MEMS chips during integration into larger assemblies, i.e. the arrangement of one or more MEMS chips on a package substrate. At the latest after integration has been completed, the protective cover is often removed again, however, in order to ensure a proper optical function of the MEMS chip.

One option for removing a protective cover of MEMS chips again if desired is described for example in the conference paper “Temporary protective packaging for optical MEMS” by L. Bogaerts et al. (44th International Symposium on Microelectronics, 9-13 Oct. 2011, Long Beach, CA, USA). For the mentioned fixed connection between the wafer that ultimately forms the actual MEMS chips, with the MEMS structures arranged thereon, and the wafer that is provided with depressions and ultimately forms the protective cover, a thermally decomposable adhesive is used. As soon as the protective cover is to be removed, the adhesive is thermally decomposed and the protective cover can be detached. The MEMS structures are then freely accessible again.

One example of optical MEMS chips is MEMS mirror arrays, in which a multiplicity of small mirror elements are each mounted so as to be individually movable relative to a common base. For each mirror element, at least one actuator is provided and enables the mirror element to be adjusted along a respectively predefined degree of freedom. Depending on the application purpose, mirror elements can be pivotable for example about two axes extending perpendicular to each other and parallel to the base, in which case enough actuators are then also provided to enable the mirror element to pivot about precisely these axes independently of each other. For the individual mirror elements, sensors can also be provided and enable the position of the mirror element to be determined relative to the base, so that the alignment of the mirrors can be monitored. An embodiment for the mirrors of a MEMS mirror array is described in DE 10 2015 204 874 A1.

Corresponding MEMS mirror arrays can be used in the production of microstructured components, such as e.g. integrated circuits, using photolithography.

For photolithography in the production of microstructured components, use is made of a projection exposure apparatus comprising an illumination system and a projection system. The image of a mask (also referred to as a reticle) illuminated by the illumination system is projected so as to reduce the size of the former onto a substrate, for example a silicon wafer, which is coated with a light-sensitive layer and arranged in the image plane of the projection system, using the projection system in order to transfer the mask structure to the light-sensitive coating of the substrate.

In general, two facet mirrors are arranged in the beam path between the actual exposure radiation source and the mask to be illuminated in the case of illumination systems, for example of projection exposure apparatuses designed for the EUV range, that is to say for exposure wavelengths of 5 nm to 30 nm, for example of 13.5 nm, and the mirrors allow homogenization of the radiation in a manner substantially comparable to the principle of a fly's eye condenser. The closer facet mirror in the beam path of the exposure radiation source is often a so-called field facet mirror, and the other facet mirror is a so-called pupil facet mirror.

In order to be able to produce different intensity and/or angle of incidence distributions during the illumination of the mask, the facets of at least one of the two facet mirrors—for example those of the field facet mirror—can be formed from a plurality of electromechanically individually pivotable micromirrors or correspondingly configured MEMS chips, for example MEMS mirror arrays. The same is correspondingly disclosed e.g. in WO 2012/130768 A2.

At an exposure wavelength of 13.5 nm, for example, protective covers of MEMS chips as currently implemented are to be removed, the protective covers are generally not sufficiently transmissive for radiation of this wavelength.

It has been found that even after removal of the protective cover, a frame remains around the actual MEMS mirror arrays, and on account of this frame an optimal fill factor might not be achieved when assembling a facet mirror made from a plurality of MEMS mirror arrays. The “fill factor” is a measure of the integration density and represents the proportion of the reflection surface of the mirrors of the MEMS mirror arrays that is formed by the individual mirrors in relation to the total surface area of the facet mirror (the so-called “fill factor”).

The reduced integration density described by way of example above with reference to facet mirrors may also be relevant to other fields of application and other kinds of MEMS chips.

### SUMMARY

The disclosure seeks to provide methods which enable MEMS chips to be post-processed and further processed in such a way that, for example, reduced integration density no longer occurs or occurs only to a reduced extent.

The disclosure provides embodiments which can achieve this.

The disclosure relates to a method for post-processing of MEMS chips comprising MEMS structures arranged on a carrier material, with at least one projection region of projecting material protruding laterally beyond the region of the MEMS chip provided with MEMS structures, wherein at least one projection region is removed by separating the projecting material from the carrier material of the MEMS chip.

Furthermore, the disclosure relates to a method for handling of MEMS chips without regions projecting beyond the MEMS structures arranged on a carrier material, for example after post-processing according to the disclosure, wherein at least one lateral depression is provided in the carrier material and the MEMS chips are handled by way of a tool engaging in the lateral depression(s).

The disclosure has recognized that material which projects laterally beyond the actual MEMS chip and which has no effects for the actual functionality of the MEMS chip may have adverse effects on the integration density, for example if a plurality of MEMS chips are intended to be arranged next to one another as closely packed as possible. This is because the projection regions in question, generally containing only functionless material, act as unwanted spacers. Corresponding projection regions are often present in MEMS chips which, during their production, are provided with a protective cover and the latter is then removed again before or during integration, however, but those regions to which the protective cover was originally secured remain as projection beyond the actual MEMS chip.

If e.g. a facet mirror for an illumination system of a projection exposure apparatus is composed of MEMS mirror arrays in which, in general, but for example in the case of EUV illumination, protective covers are to be removed before or during integration—for example the arrangement of the MEMS mirror arrays on a package substrate—then between the individual MEMS mirror arrays, on account of the projections, distances between the respectively adjacent mirrors of two adjacent MEMS mirror arrays arise which are larger than the distances between the mirrors of one of the MEMS mirror arrays. This not only has adverse effects on the fill factor of a mirror constructed in this way, e.g. a facet mirror, but can also contribute to the creation of unwanted stray light that may arise on account of reflection or scattering of incident radiation on the material in the projection regions. Moreover, projection regions often have the effect that the individually controllable mirrors of a facet mirror comprising a multiplicity of MEMS mirror arrays are not actually arranged in a uniform grid, which can make the configuration and control of such a facet mirror more difficult. Comparable issues may also arise in other applications of MEMS chips.

The present disclosure relates not only to a method by which existing projection regions of MEMS chips can subsequently be removed, but also to a method for handling of MEMS chips that do not have any projection regions, for example because they were post-processed according to the disclosure or because they were produced fundamentally without projection regions.

Existing but unwanted projection regions are removed according to the disclosure by separating the projecting material from the carrier material of the MEMS chip. The projecting material is thus detached from the carrier material of the MEMS chip and can thereafter be removed without problems.

For removing at least one projection region, it is possible to create a continuous gap between projection region and carrier material of the MEMS chip. As a result of creating the continuous gap, the material in the projection region is directly and completely separated from the carrier material of the MEMS chip, in which case a clean edge of the carrier material can generally be attained.

It is also possible to remove at least one projection region by creating a predetermined breaking location between projection region and carrier material of the MEMS chip and subsequently breaking up the predetermined breaking location. This means that the material in the projection region can be separated in a controlled manner—specifically for example by the tool or the like that applies the force used for the breaking up—and can then also be removed directly. The predetermined breaking location can be attained by weakening the structure in this region, for example by partly removing material or by weakening the material itself. If a predetermined breaking location to be created, in a projection region, is made too large or is configured in such a way that clean separation of the entire predetermined breaking location all at once is not ensured, the projection region can also be subdivided into individual sections which, by way of creating gaps and/or predetermined breaking locations among one another, are separated from one another such that the sections can be detached individually by breaking up the respectively assigned predetermined breaking locations between projecting material and carrier material.

It is possible to combine the two alternatives mentioned above in respect of separating projecting material. In this regard, e.g. in the case of a MEMS chip with a plurality of projection regions, one portion thereof can be removed in each case by creating a continuous gap, and another portion by creating a predetermined breaking location and subsequent breaking away.

A combination of both measures described for an individual projection region is also conceivable. For example, creating a predetermined breaking location for separating a projection region can comprise creating a continuous gap in further regions and obtaining thin material bridges only in small regions, which bridges then function as predetermined breaking locations.

In order to avoid collisions between the material separated as a result of creating a continuous gap or as a result of breaking up a suitably created predetermined breaking location and the carrier material or for example the MEMS structures on the carrier material, which could be damaged as a result, suitable measures can be provided. By way of example, the material in the projection region, prior to the separation thereof from the carrier material, can be connected to a tool, or the like, to which it remains connected even after separation and can thus be taken away from the carrier material in a controlled manner.

For creating a continuous gap and/or a predetermined breaking location, sacrificial material that is arranged in the corresponding region and differs at least from the projecting material, in general also from the carrier material, can be removed. The sacrificial material may have been introduced during the production of the MEMS chips, such that after its removal in the course of the method according to the disclosure, only material bridges provided for creating a predetermined breaking location remain or else any structural connection between carrier material and the material in the projection region is eliminated, whereby a continuous gap is created. However, it is also possible to introduce the sacrificial material using suitable structuring methods only after the production of the MEMS chips and optionally even after at least partial integration of the MEMS chip in a larger assembly or an arrangement on a package substrate.

The sacrificial material can be removed by an etching process. In this embodiment variant, the sacrificial material can be chosen in such a way that it can be removed without residues by an etching method in which for example the carrier material and the MEMS structures of the MEMS chip are not attacked. With knowledge of the substances used for the carrier material and the MEMS structures, a person skilled in the art can generally determine a suitable sacrificial material without further effort.

For example if the intention is to employ a directional etching method exclusively proceeding from the side of the carrier material facing away from the MEMS structures, it is also possible to protect the carrier material at least in the region of the MEMS chip from damage during the etching process by providing suitable protective layers.

Furthermore, provision can be made for accommodating the MEMS chip in an etching encapsulation for a time for the removal of sacrificial material using an etching process, which encapsulation spatially delimits the volume to be filled with a suitable etching medium—i.e. for example etching gas or etching liquid. In this case, the etching encapsulation can have an inlet and an outlet in order to be able to produce a flow of etching medium in the volume delimited by the etching encapsulation, which flow can accelerate the etching process. If a protective cover is provided and in a manner also still spanning the MEMS chip at the time of the envisaged etching process, through channels that have already been introduced into the protective cover beforehand or through openings created therein only on a short-term basis, etching medium can be introduced into the region encapsulated by the protective cover and can also be removed again. In this case, the protective cover itself serves as an etching encapsulation.

As an alternative to the etching process, it is possible for the sacrificial material to be thermally decomposable. For removing the sacrificial material, the MEMS chip can then be heated to a sufficient temperature at which the sacrificial material decomposes and a continuous gap and/or a predetermined breaking location are/is thus created.

For creating a continuous gap and/or a predetermined breaking location, material can also be removed without residues, for example by high-energy radiation. For this purpose, it is possible to use e.g. a focused particle beam, for example a focused ion beam (FIB), such as a focused gallium ion beam, for ablation or for gas-assisted etching, or else a high-energy laser for laser ablation.

For creating a predetermined breaking location, provision can also be made for weakening in a targeted manner the material in the region of the predetermined breaking location to be created, optionally by irradiation. The weakening can be effected by changing the crystal structure, for example by breaking down an existing mono-and/or polycrystalline structure to form an amorphous structure. A laser beam or an ion beam, for example, can be used for this purpose. Using suitable focusing of a laser beam to which the material is transparent, in general, it is also possible to attain an inner weakening of the material by breaking down the structure.

An at least temporary weakening of the material in the region of a predetermined breaking location can also be achieved by a reduction of the density by local heating of the material. A heat input used for this can be effected e.g. by a suitable laser beam.

In general, what is common to all the above methods comprising an irradiation is that the beam used for the irradiation, for example the laser or particle beam, for example ion beam, generally is strongly focused to a point or a line. However, correspondingly focused radiation can have an—albeit generally very small—numerical aperture which regularly obstructs creation of a continuous gap and/or a predetermined breaking location directly at the edge of the carrier material of the MEMS chip at least if the radiation can be introduced exclusively perpendicularly—i.e. with an angle of incidence of 0°—with respect to the carrier material. For example, in this case there is otherwise the risk of parts of the MEMS structures situated at the edge of the MEMS chip being hit and damaged by the incident beam as a result of the expansion thereof. A suitable selection of the angle of incidence—if adjustable—makes it possible to reduce or completely avoid this risk. As an alternative thereto, it is possible to use a radiation source which emits a collimated beam (i.e. a beam having exclusively parallel rays), the beam being limited to the desired site of action using a shadow mask. Depending on the extent of the beam, for example even a linearly extending site of action can be irradiated simultaneously by way of suitable design of the shadow mask.

If a predetermined breaking location has been created, it can be broken up by introducing shear stress and/or tensile stress, as a result of which the projecting material is separated from the carrier material and can be removed. A tensile stress on the predetermined breaking location can occur if the projecting material, in the plane of the carrier material of the MEMS chip, is pulled away from the carrier material; a shear stress can occur if an opposing force perpendicular to the plane of the carrier material is in each case applied to the carrier material and the projecting material, the direction in which the force acts on the carrier material being unimportant. The force can act directly on the carrier material or the projecting material. However, it is also possible to introduce the force on the projecting material indirectly by acting on a protective cover that is still present at this point in time. Suitable pressing or pulling tools can be used for this purpose, wherein pulling tools can be connected by suction to the component to be pulled.

It is also possible to break up a created predetermined breaking location by changing the temperature and/or by introducing a temperature gradient. Especially if the predetermined breaking location has been created by weakening the material in this region, suitably changing the temperature enables the predetermined breaking location to be broken up. In this case, it can be used to ensure that the change in temperature in the region of the predetermined breaking location, adjacent thereto and/or in the entire MEMS chip does not damage either the carrier substrate or the MEMS structures.

As already mentioned several times, at least one projection region that is to be removed may have been originally configured for attaching a protective cover for the MEMS chip. The protective cover may already have been removed prior to separating the material in a projection region; however, it is also possible for the protective cover to be removed at the same time as the projection region. In other words, at the time of creating a continuous gap or breaking up a created predetermined breaking location, the protective cover is thus intended to still be connected to the material to be separated. The handling of the separated material and for example the avoidance of damage to the MEMS structure as a result of collision thus often become more easily possible.

The MEMS chip from which at least one projection region is removed can be a MEMS mirror array, such as a MEMS mirror array for photolithography, for example a MEMS mirror array for EUV photolithography. The latter can have for example by mirror surfaces that are reflective for radiation of a wavelength of 13.5 nm.

According to the post-processing method explained above—provided that all projection regions present are removed—MEMS chips limited exclusively to the region of the MEMS structure and the carrier material carrying the latter are available. Of course, it is also possible to avoid corresponding projection regions at least in part as early as during the production of MEMS chips, such that at least the number of projection regions to be removed by the method described above can be reduced - possibly even to zero.

In this regard, it is conceivable, for example, when dividing a wafer on which MEMS structures for a plurality of MEMS chips are applied, to guide at least a portion of the cutting lines along the MEMS structures in such a way that after the corresponding cut has been made along this cutting line, no projection regions occur at least at a portion of the MEMS chips adjacent thereto.

As an alternative thereto, it is possible, as early as during the production of the MEMS structures, to structure the carrier material of the wafer such that, in a generally late step of the production method, continuous gaps are introduced into the carrier material and directly divide the carrier material into the individual MEMS chips, in which case at least the number of projection regions can be reduced. It is even possible in this way to produce MEMS chips without any projection regions.

Irrespective of whether possibly still existing projection regions are removed by the method according to the disclosure as explained above, availability—resulting at the latest therefrom—of a MEMS chip without any projection regions involves altered handling of MEMS chips by comparison with certain known approaches. Corresponding projection regions—as already mentioned—are regularly used for securing protective covers, which in certain known approaches are in turn used for marking purposes—for example as an orientation and alignment aid for a MEMS chip. Furthermore, the projection regions are regularly used as engagement points for handling, e.g. by way of a tool. With the projection regions being omitted, for example on account of the method according to the disclosure, there is a desire for alternative methods for handling of MEMS chips without regions projecting beyond the MEMS structures arranged on a carrier material.

The disclosure relates to a method for handling of MEMS chips without regions projecting beyond the MEMS structures arranged on a carrier material. In this case, a corresponding MEMS chip may have been created by post-processing according to the disclosure, although this is not necessary.

Corresponding “frameless” MEMS chips are handled according to the disclosure by way of a suitable tool engaging in one or more lateral depressions in the carrier material. In this case, the term “lateral depressions” denotes depressions at the end faces of the carrier material. Especially the side of the carrier material on which the MEMS structures are arranged and also the opposite side relative thereto are thus free of the aforementioned depressions provided for the engagement of tools for handling purposes.

It can be desirable for at least two lateral depressions to be provided on two mutually adjacent sides of the carrier material. The carrier material or the MEMS chip can then be gripped and handled such that the other sides of the carrier material are free, which enables small spacings with respect to adjacent MEMS chips during integration since there is no need for spacings between the MEMS chips in which a handling tool would have to be guided between the MEMS chips. In order to avoid relative movements between the MEMS chip and the handling tool, such as tilting, it can be desirable to provide three lateral depressions, wherein two depressions thereof can be provided on the same side of the carrier material.

If depressions are provided only on two adjacent sides of the carrier material, but at least one side of the carrier material is depression-free, the orientation of the MEMS structures of the MEMS chip vis-à-vis the carrier material can be read from the arrangement of the depressions, as a result of which the correct alignment of the MEMS chip can be ensured during the integration thereof.

Alternatively or additionally, markings can be arranged laterally on the carrier material. Besides reference markings used for the correct orientation of the MEMS chips during integration, identifications, e.g. in a form similar to a barcode, can also be arranged laterally on the carrier material. The markings can also be configured as depressions or a group of depressions.

Both the lateral depressions for engagement of a tool and markings—if the latter are provided as depression—can be introduced subsequently after the production of a MEMS chip. However, it is also possible to provide the carrier material with sacrificial material in the regions provided as depression. For example, the carrier material as early as in the wafer state can be provided with then internal sacrificial material which is then exposed by the wafer being separated into individual MEMS chips and is subsequently removed.

As an alternative to the handling of a MEMS chip by engagement in lateral depressions of the carrier material, it is also possible—depending on the configuration of the MEMS chip—to implement handling by engaging directly on the MEMS structures. If the MEMS chip is a mirror array, a suction plate having a number of suction openings corresponding to the number and arrangement of the individual mirrors can be used to create a fixed connection between each individual mirror of the mirror array and the suction plate, with the result that—provided that the MEMS structures have a sufficient loading capacity—handling is possible solely by engagement on the MEMS structures.

It is also possible, for handling of MEMS chips by engagement on the MEMS structures, to have recourse to electrostatic grippers, van der Waals grippers, vacuum grippers, Bernoulli grippers and ultrasonic grippers. In the case of Bernoulli grippers, the distance below which the gas flow is switched on is chosen such that a sufficient gripping force is present and—in the case of a MEMS mirror array as MEMS chip—the vibration excitations of the mirrors as a result of the air flow remain in an acceptable range.

### BRIEF DESCRIPTION OF THE DRAWINGS

Embodiments of the disclosure will now be described by way of example on the basis of embodiments with reference to the accompanying drawings, in which:

FIG. 1: shows a schematic illustration of a projection exposure apparatus for photolithography comprising produced MEMS mirror arrays according to the disclosure;

FIGS. 2a-e: show a schematic illustration of methods according to the disclosure for post-processing of MEMS chips;

FIGS. 3a-d: show a schematic illustration of possible configuration variants of the separating regions from FIG. 2;

FIGS. 4a, b: show a schematic illustration in regard to introducing high-energy radiation into a separating region in accordance with FIG. 2;

FIGS. 5a-c: show a schematic illustration in regard to separation of separating regions configured as predetermined breaking locations from FIG. 2;

FIGS. 6a-c: show a schematic illustration of tools for separating predetermined breaking locations in accordance with FIG. 5;

FIGS. 7a, b: show a schematic illustration in regard to removing sacrificial material from separating regions in accordance with FIG. 2;

FIGS. 8a-c: show a schematic illustration in regard to producing MEMS chips with and without projection regions; and

FIGS. 9a, b: show a schematic illustration in regard to handling MEMS chips without projection regions.

### DETAILED DESCRIPTION

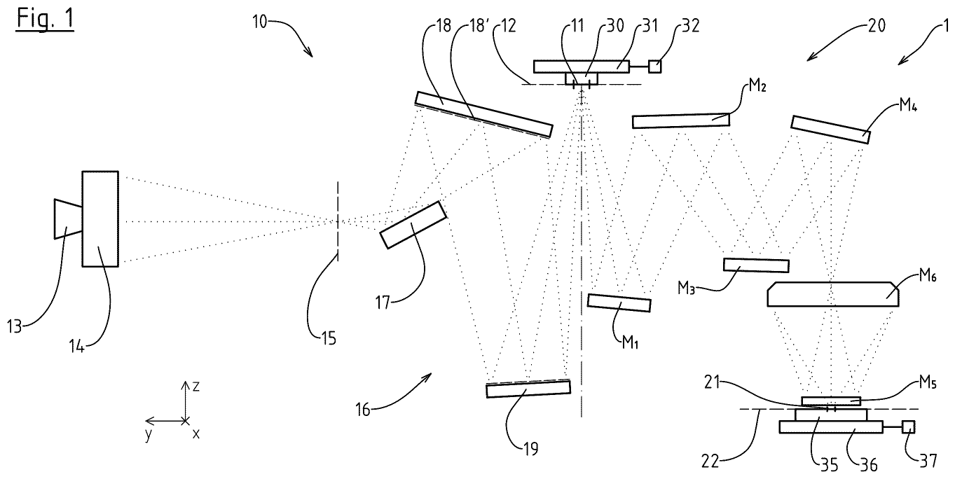

FIG. 1 illustrates a schematic meridional section of a projection exposure apparatus 1 for photolithography. In this case, the projection exposure apparatus 1 comprises an illumination system 10 and a projection system 20.

An object field 11 in an object plane or reticle plane 12 is illuminated with the aid of the illumination system 10. To this end, the illumination system 10 comprises an exposure radiation source 13, which, in the illustrated exemplary embodiment, emits illumination radiation at least comprising used light in the EUV range, that is to say with a wavelength of between 5 nm and 30 nm for example. The exposure radiation source 13 can be a plasma source, for example an LPP (laser produced plasma) source or a GDPP (gas discharge produced plasma) source. It can also be a synchrotron-based radiation source. The exposure radiation source 13 can also be a free electron laser (FEL).

The illumination radiation emerging from the exposure radiation source 13 is initially focused in a collector 14. The collector 14 can be a collector with one or with a plurality of ellipsoidal and/or hyperboloidal reflection surfaces. The illumination radiation can be incident on the at least one reflection surface of the collector 14 with grazing incidence (GI), that is to say at angles of incidence of greater than 45°, or with normal incidence (NI), that is to say at angles of incidence of less than 45°. The collector 14 can be structured and/or coated on the one hand for optimizing its reflectivity for the used radiation and on the other hand for suppressing extraneous light.

Downstream of the collector 14, the illumination radiation propagates through an intermediate focus in an intermediate focal plane 15. If the illumination system 10 is constructed in a modular design, the intermediate focal plane 15 can be used, in general, for the separation—including the structural separation—of the illumination system 10 into a radiation source module, comprising the exposure radiation source 13 and the collector 14, and the illumination optical unit 16 described below. In the case of a corresponding separation, radiation source module and illumination optical unit 16 then jointly form a modularly constructed illumination system 10.

The illumination optical unit 16 comprises a deflection mirror 17. The deflection mirror 17 can be a plane deflection mirror or alternatively a mirror with a beam-influencing effect going beyond the pure deflection effect. Alternatively or additionally, the deflection mirror 17 can be embodied as a spectral filter separating a used light wavelength of the illumination radiation from extraneous light having a wavelength that deviates therefrom.

The deflection mirror 17 is used to deflect the radiation emanating from the exposure radiation source 13 to a first facet mirror 18. If—as in the present case—the first facet mirror 18 is arranged in a plane of the illumination optical unit 16 which is optically conjugate to the reticle plane 12 as a field plane, this facet mirror is also referred to as a field facet mirror.

The first facet mirror 18 comprises a multiplicity of micromirrors 18′ that are individually pivotable about two mutually perpendicular axes in each case, for the purpose of controllably forming facets which are each optionally configured with an orientation sensor (not depicted here) for determining the orientation of the micromirror 18′. The first facet mirror 18 is thus a microelectromechanical system (MEMS system), as also described in DE 10 2008 009 600 A1, for example.

A second facet mirror 19 is arranged downstream of the first facet mirror 18 in the beam path of the illumination optical unit 16, with the result that this yields a doubly faceted system, the fundamental principle of which is also referred to as a fly's eye integrator. If the second facet mirror 19—as in the depicted exemplary embodiment—is arranged in a pupil plane of the illumination optical unit 16, it is also referred to as a pupil facet mirror. However, the second facet mirror 19 can also be arranged at a distance from a pupil plane of the illumination optical unit 16, as a result of which a specular reflector arises from the combination of the first and the second facet mirror 18, 19, for example as described in US 2006/0132747 A1, EP 1 614 008 B1 and U.S. Pat. No. 6,573,978.

Optionally, the second facet mirror 19 is not constructed from pivotable micromirrors, but rather can comprise individual facets formed from one mirror or a manageable number of mirrors which are significantly larger than micromirrors, which facets are either stationary or tiltable only between two defined end positions. It is however—as illustrated—also possible, in the second facet mirror 19, to provide a microelectromechanical system having a multiplicity of micromirrors 19′ that are individually pivotable about two mutually perpendicular axes in each case, each optionally comprising an orientation sensor.

The individual facets of the first facet mirror 18 are imaged into the object field 11 with the aid of the second facet mirror 19, with this regularly only being approximate imaging. The second facet mirror 19 can be the last beam-shaping mirror or else actually the last mirror for the illumination radiation in the beam path upstream of the object field 11.

In each case one of the facets of the second facet mirror 19 is assigned to exactly one of the facets of the first facet mirror 18 for the purpose of forming an illumination channel for illuminating the object field 11. This can for example result in illumination according to the Köhler principle.

The facets of the first facet mirror 18 are imaged overlaid on one another by way of a respective assigned facet of the second facet mirror 19, for the purpose of illuminating the object field 11. Here, the illumination of the object field 11 is as homogeneous as possible. It can have a uniformity error of less than 2%. Field uniformity can be achieved by overlaying different illumination channels.

By selecting the ultimately used illumination channels, which is possible without problems by way of a suitable setting of the micromirrors 18′ of the first facet mirror 18, it is still possible to set the intensity distribution in the entrance pupil of the projection system 20 described below. This intensity distribution is also referred to as illumination setting. Incidentally, it may be desirable here to arrange the second facet mirror 19 not exactly in a plane that is optically conjugate to a pupil plane of the projection system 20. For example, the pupil facet mirror 19 can be arranged so as to be tilted relative to a pupil plane of the projection system 20, as is described in DE 10 2017 220 586 A1, for example.

In the arrangement of the components of the illumination optical unit 16 as illustrated in FIG. 1, however, the second facet mirror 19 is arranged in an area conjugate to the entrance pupil of the projection system 20. Deflection mirror 17 and the two facet mirrors 18, 19 are arranged tilted both vis-à-vis the object plane 12 and vis-à-vis one another in each case.

In an alternative embodiment (not illustrated) of the illumination optical unit 16, a transfer optical unit comprising one or more mirrors can additionally be provided in the beam path between the second facet mirror 19 and the object field 11. The transfer optical unit can for example comprise one or two normal-incidence mirrors (NI mirrors) and/or one or two grazing-incidence mirrors (GI mirrors). Using an additional transfer optical unit, it is possible for example to take account of different poses of the entrance pupil for the tangential and for the sagittal beam path of the projection system 20 described below.

It is alternatively possible for the deflection mirror 17 illustrated in FIG. 1 to be dispensed with, for which purpose the facet mirrors 18, 19 should then be suitably arranged vis-à-vis the radiation source 13 and the collector 14.

The object field 11 in the reticle plane 12 is transferred to the image field 21 in the image plane 22 with the aid of the projection system 20.

For this purpose, the projection system 20 comprises a plurality of mirrors Mᵢ, which are consecutively numbered in accordance with their arrangement in the beam path of the projection exposure apparatus 1.

In the example illustrated in FIG. 1, the projection system 20 comprises six mirrors M₁ to M₆. Alternatives with four, eight, ten, twelve or any other number of mirrors Mᵢ are likewise possible. The penultimate mirror M₅ and the last mirror M₆ each have a passage opening for the illumination radiation, as a result of which the illustrated projection system 20 is a doubly obscured optical unit. The projection system 20 has an image-side numerical aperture that is greater than 0.3 and can also be greater than 0.6, and can be for example 0.7 or 0.75.

The reflection surfaces of the mirrors Mᵢ can be in the form of freeform surfaces without an axis of rotational symmetry. However, the reflection surfaces of the mirrors Mᵢ can alternatively also be designed as aspherical surfaces with exactly one axis of rotational symmetry of the reflection surface shape. Just like the mirrors of the illumination optical unit 16, the mirrors Mᵢ can have highly reflective coatings for the illumination radiation. These reflective coatings can be designed as multilayer coatings, for example with alternating layers of molybdenum and silicon.

The projection system 20 has a large object-image offset in the y-direction between a y-coordinate of a center of the object field 11 and a y-coordinate of the center of the image field 21. This object-image offset in the y-direction can be of approximately the same magnitude as a z-distance between the object plane 12 and the image plane 22.

For example, the projection system 20 can be designed to be anamorphic, that is to say it has different imaging scales βₓ, β_{y} in the x- and y-directions for example. The two imaging scales βₓ, β_{y} of the projection system 20 can be (βₓ, β_{y})=(+/−0.25, /+−0.125). An imaging scale β of 0.25 corresponds here to a reduction with a ratio 4:1, while an imaging scale β of 0.125 results in a reduction with a ratio of 8:1. A positive sign in the case of the imaging scale β means imaging without image inversion; a negative sign means imaging with image inversion.

Other imaging scales are likewise possible. Imaging scales βₓ, β_{y} with the same sign and the same absolute magnitude in the x- and y-directions are also possible.

The number of intermediate image planes in the x-direction and in the y-direction in the beam path between the object field 11 and the image field 21 can be the same or different, depending on the embodiment of the projection system 20. Examples of projection systems 20 with different numbers of such intermediate images in the x-direction and y-direction are known from US 2018/0074303 A1.

For example, the projection system 20 can comprise a homocentric entrance pupil. The latter can be accessible. However, it can also be inaccessible.

A reticle 30 (also referred to as mask) arranged in the object field 11 is exposed by the illumination system 10 and transferred by the projection system 20 onto the image plane 21. The reticle 30 is held by a reticle holder 31. The reticle holder 31 is displaceable by way of a reticle displacement drive 32 for example in a scanning direction. In the exemplary embodiment illustrated, the scanning direction runs in the y-direction.

A structure on the reticle 30 is imaged onto a light-sensitive layer of a wafer 35 arranged in the region of the image field 21 in the image plane 22. The wafer 35 is held by a wafer holder 36. The wafer holder 36 is displaceable by way of a wafer displacement drive 37 for example along the y-direction. The displacement, firstly, of the reticle 30 by way of the reticle displacement drive 32 and, secondly, of the wafer 35 by way of the wafer displacement drive 37 can be implemented so as to be synchronized with one another.

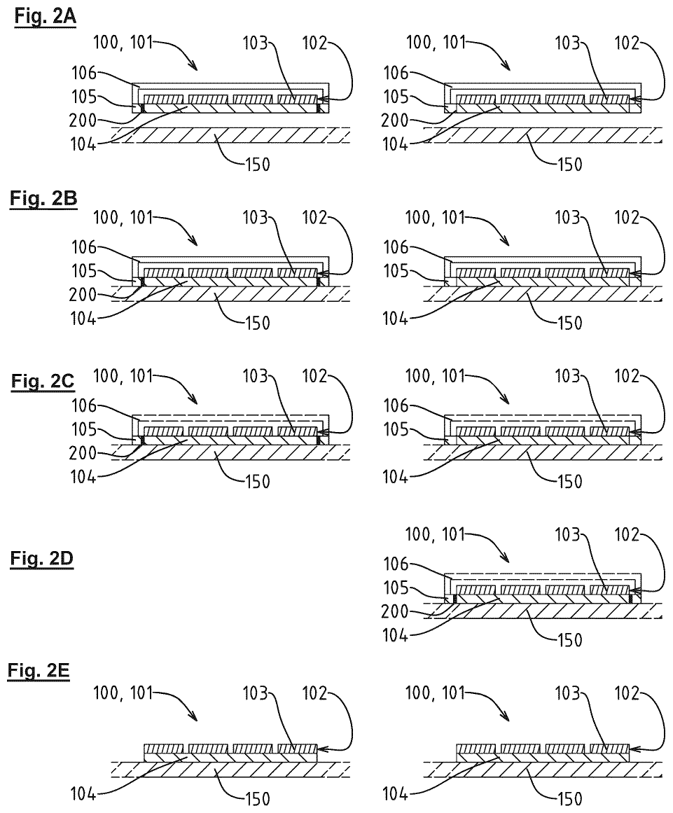

The projection exposure apparatus 1 illustrated in FIG. 1, or its illumination system 10, the above description of which reflects known technology, includes the first and/or second facet mirror 18, 19 comprising one or more MEMS chips 100 post-processed according to the disclosure (cf. FIGS. 2a-e, inter alia), namely for example MEMS mirror arrays 101. Each of the MEMS chips 100 here has a multiplicity of individual mirrors 103 adjustable independently by in each case two degrees of freedom of rotation as parts of a MEMS structure 102, which are arranged in a two-dimensional grid. Each of the facet mirrors 18, 19 can be formed by a single or a plurality of MEMS chips 100 or MEMS mirror arrays 101 arranged next to one another.

As is known, corresponding MEMS mirror arrays 101 are produced jointly with a multiplicity of other MEMS mirror arrays 100 or other MEMS chips 100 on a common wafer and are covered with further wafers provided with suitable depressions, such that when the wafer is subsequently divided into individual MEMS mirror arrays 101 or MEMS chips 100, a respective protective cover 106 for each individual MEMS mirror array 100 is maintained.

FIG. 2a schematically shows a sectional illustration of two examples of MEMS chips 100 or MEMS mirror arrays 101 such as are present in general after a wafer has been divided. In the case of the MEMS chips 100 or MEMS mirror arrays 101, the actual MEMS structure 102—i.e. the individual mirrors 103 and also all components used for systematic pivoting—is arranged on a carrier material 104.

In this case, the carrier material 104 extends laterally beyond the region in which the MEMS structures 102 are arranged, and thus forms a projection region 105 composed of projecting material. These projection regions 105 serve for attaching the protective cover 106 extending over the MEMS structures 102. The protective cover 106 can be fixedly connected to the projection regions 105 e.g. with the aid of an adhesive. Other joining methods, such as e.g. an anodic bonding method, are likewise possible for connecting the protective cover 106 to the projection regions 105.

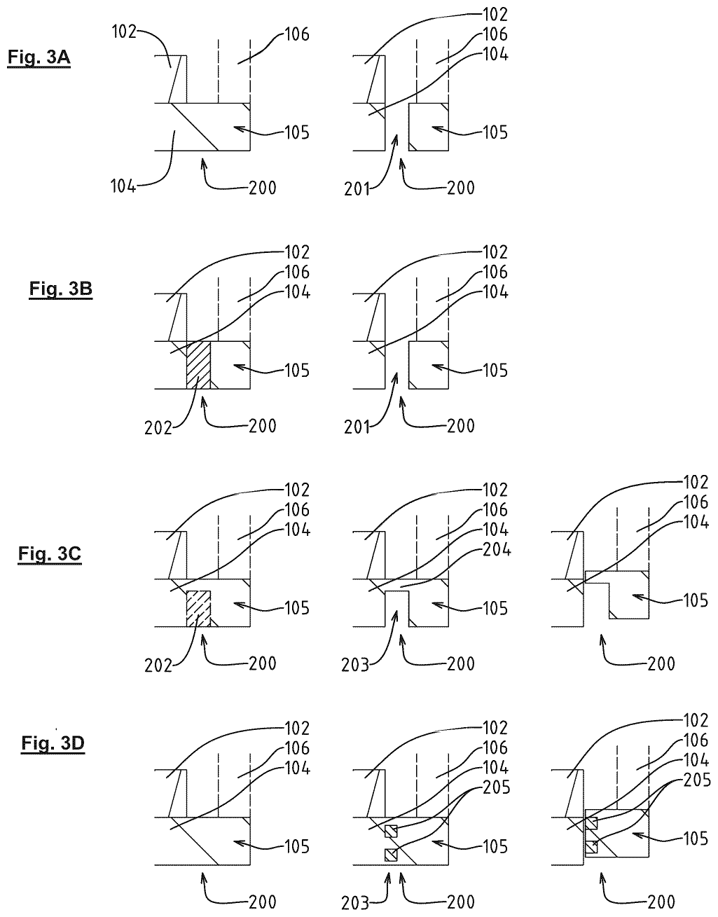

In the embodiment variant illustrated on the left in FIG. 2a, a separating region 200 has already been formed between the carrier material 104 in the region provided with MEMS structures 102 and the projection regions 105, which separating region will be explained in even greater detail below in association with FIGS. 3a-d. In the embodiment variant illustrated on the right in FIG. 2b, a corresponding separating region 200 is not (yet) provided.

FIG. 2a likewise illustrates a package substrate 150, on which the MEMS chip 100 or the MEMS mirror array 101 is intended to be arranged or is arranged. In this case, the extent of the package substrate 150 can be adapted to the extent of the region of the carrier material 104 that is provided with MEMS structures 102. However, it is also possible for the package substrate 150 to be significantly larger than the region in question, which is indicated by the dashed parts of the package substrate 150 in FIGS. 2a-e.

Even though FIGS. 2a-e show that as a matter of principle, it is also possible for the method according to the disclosure to be carried out without the provision of a package substrate 150, i.e. solely with the actual MEMS chip 100. In this case, the step illustrated in FIG. 2b should be skipped and the package substrate 150 should be disregarded in each of the subsequent figures.

Specifically, FIG. 2b illustrates that the MEMS chip 100 or the MEMS mirror array 101 is fixedly connected to the package substrate 150. If the package substrate 150 extends beyond the region of the carrier material 104 that is provided with MEMS structures 102, the projection regions 105 and optionally the separating region 200 should if possible not be connected to the package substrate 150.

In a next step, the protective cover 106 can optionally be removed, which is why it is merely illustrated in a dashed manner in FIG. 2c. The protective cover 106 can be removed by way of releasing the adhesive connection between protective cover 106 and projection region 105. If the adhesive used is a thermally decomposable adhesive, e.g. the temperature can be suitably increased at least locally. Other separating methods are also possible, of course. The fact of whether or not the protective cover 106 is to be removed is dependent on the configuration of the already existing separating region 200 (FIG. 2c, on the left) or of the separating region 200 yet to be created subsequently (FIG. 2c, on the right). What is especially relevant here is whether the separating region 200 is to be accessible from the regions covered by the protective cover 106, which will generally be the case especially in the case of an already implemented arrangement on a package substrate 150; if a package substrate 150 is not (yet) present, the separating region 200 is accessible from the side of the carrier material 104 facing away from the MEMS structures 102, and so the protective cover 106 possibly is not removed in the step illustrated in FIG. 2c.

If the separating region 200 has not yet been formed (FIG. 2c, on the right), this has to be done in the next step (FIG. 2d, on the right). Possibilities concerning the configuration of the separating region 200 will be described in greater detail below in association with FIGS. 3a-d.

Finally, the projection regions 105 are separated at the separating regions 200 and removed (FIG. 2e). If the protective cover 106 was still fixedly connected to the projection regions 105, projection regions 105 and protective cover 106 can be removed as a unit. Some possible methods for actually removing the projection regions 105 and protective cover 106 will be discussed in association with FIGS. 5a to 7b.

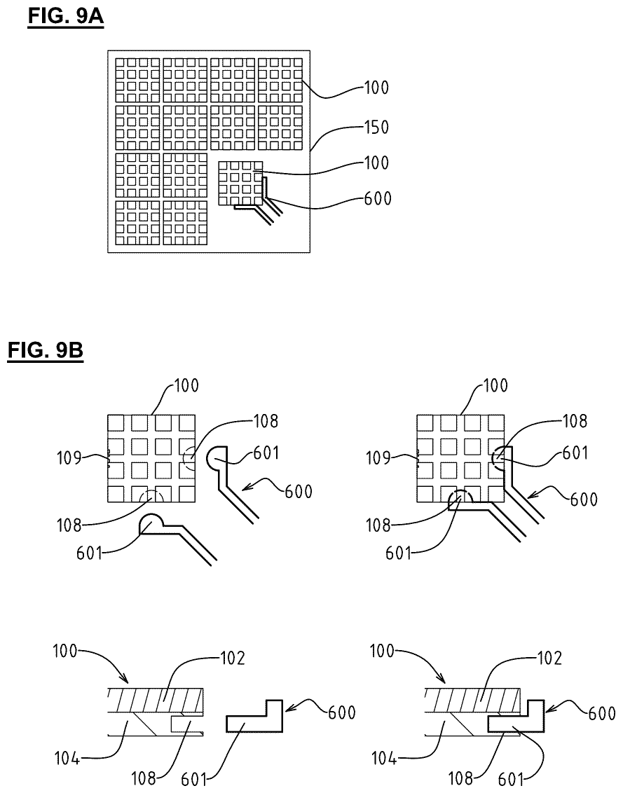

If the MEMS chip 100 had not already been arranged on a package substrate 150 beforehand, the MEMS chip 100 can be arranged on a package substrate at the latest at this point in time, which will be explained further in association with FIGS. 9a-b.

FIGS. 3a-d schematically depicts various configurations of separating regions 200 or methods for separating projecting material in projection regions 105.

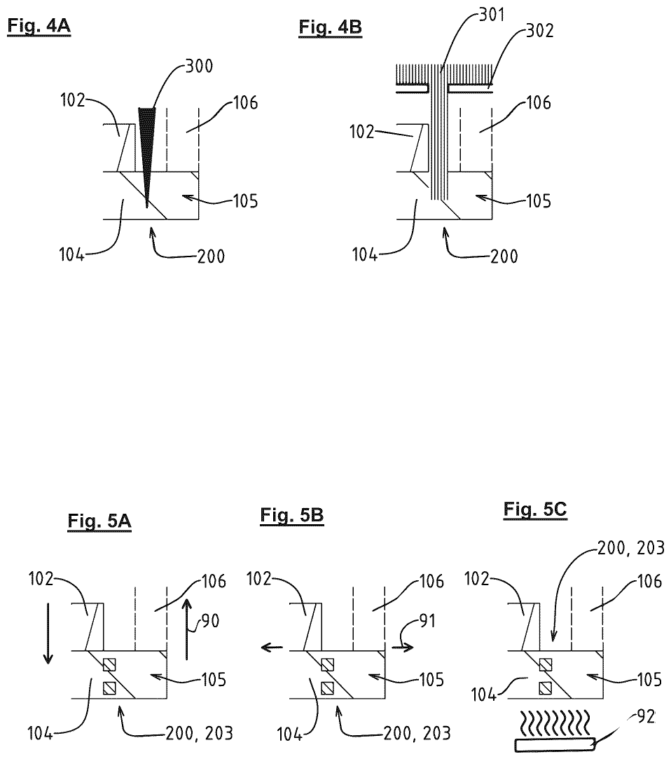

In FIG. 3a, the separating region 200 is not especially configured in the initial state (FIG. 3a, on the left). Rather, the carrier material 104 extends over the separating region 200 into the projection region 105. For the purpose of separating the projection region 105, provision is made for creating a continuous gap 201 between projection region 105 and carrier material 104 of the MEMS chip 100 by virtue of the material situated there in the initial state being removed without residues (FIG. 3a, on the right). In this case, removal can be effected for example by high-energy radiation, such as e.g. ion radiation or laser radiation. Possible embodiment variants for this purpose will be described below with reference to FIGS. 4a-b.

The high-energy radiation can be applied to the separating region 200 from the side of the carrier material 104 that is provided with MEMS structures 102 and/or from the opposite side relative thereto. Once the continuous gap 201 has been completed, the projection region 105 and a protective cover 106 possibly still connected thereto have been directly separated from the carrier material 104 and can be directly removed.

FIG. 3b shows an alternative procedure for creating a continuous gap 201 between carrier material 104 and projection region 105. Here in the initial state (FIG. 3b, on the left), a sacrificial material 202 that differs both from the carrier material 104 and from the projecting material in the projection region 105 is provided in the separating region 200. The sacrificial material 202 can be introduced into the carrier material 104 for example during the production of the MEMS structures 102 or may have already been introduced at this point in time.

In order to create a continuous gap 201, it is merely used to remove the sacrificial material 202. In this case, the sacrificial material 202 can be removed for example using an etching process, wherein a suitable selection of sacrificial material 202 and etchants makes it possible to ensure that neither the carrier material nor the MEMS structures 102 incur damage. Alternatively, the sacrificial material 202 can be thermally decomposable and the continuous gap 201 is created by sufficient heating of at least the sacrificial material 202. It goes without saying that it is also possible to remove the sacrificial material 202 using suitable high-energy radiation.

After the sacrificial material 202 has been completely removed, the continuous gap 201 has been created, as a result of which the projection region 105 and a protective cover 106 possibly still connected thereto have been directly separated from the carrier material 104. Projection region 105 and/or protective cover 106 can then be directly removed.

In the embodiment variant in accordance with FIG. 3c, a continuous gap 201 (cf. FIGS. 3a, b) is not created, rather a predetermined breaking location 203 is created, in which the material in the separating region 200 is reduced to a thin and easily breakable material bridge 204. The position and the rest of the configuration of the material bridge 204 within the separating region 200 can be chosen as desired, wherein an edge position vis-à-vis the carrier material 104, such as is illustrated by way of example in FIG. 3c, middle, is desirable since creating it involves processing of the MEMS chip 100 only on one side.

For creating the predetermined breaking location 203, it is possible to have recourse to the processes described in association with FIG. 3a and FIG. 3b, specifically removing material without residues in the separating region 200 using high-energy radiation or by removing sacrificial material 202 already introduced in this region beforehand. For explanation of these processes, reference is made to the statements above. It is desirable that the material bridge 204 remains in the embodiment variant in accordance with FIG. 3c.

After the predetermined breaking location 203 has been created, the projection region 105 and a protective cover 106 possibly still connected thereto can be released from the carrier material 104 by breaking up the predetermined breaking location 203 and can subsequently be removed. Variants in regard to breaking up the predetermined breaking location 203 will also be explained with reference to FIGS. 5a to 7b.

FIG. 3d illustrates a further alternative for creating a predetermined breaking location 203. Proceeding from a separating region 200 beyond which the carrier material 104 extends right into the projection region 105 (FIG. 3d, on the left), material in the region of the predetermined breaking location 203 to be created is weakened in a targeted manner. This is illustrated by weakening regions 205 in FIG. 3d, middle. In this regard, e.g. using suitable radiation, the crystal structure of the carrier material 104 in the weakening regions 205 can be broken down, i.e. e.g. transformed from a mono- and/or polycrystalline structure to an amorphous structure. Moreover, local heating can lead to a reduction of the density in the weakening regions 205 and hence weakening of the material.

After weakening has been effected, the predetermined breaking location 203 thus created can be broken up, as a result of which the projection region 105 and a protective cap 106 possibly still connected thereto are separated from the carrier material 104 and can be removed.

In all of the processes described above with reference to FIGS. 3a-d that use high-energy radiation to create a continuous gap 201 or a predetermined breaking location 203, it should be noted that corresponding radiation 300 (cf. FIG. 4a), even if it is strongly focused, has an—albeit generally very small—numerical aperture which can hamper irradiation especially on the side of the carrier material 104 with the MEMS structure 102 arranged thereon. On account of the numerical aperture—at least if the angle of incidence for the radiation is fixed at 0°, although this is regularly the case—it is virtually impossible, during irradiation of the side of the carrier material 104 with the MEMS structure 102 arranged thereon, to create a continuous gap 201 or a predetermined breaking location 203 directly adjacent to the region of the carrier material 104 that is actually provided with the MEMS structure 102. In a corresponding procedure, the MEMS structure 102 would practically inevitably be hit by the focused radiation 300 and detrimentally affected.

As an alternative thereto, it is however possible—as depicted schematically in FIG. 4b—to use a collimated beam 301 (i.e. a beam having exclusively parallel rays), the beam 301 being limited to the separating region 200 using a suitable shadow mask 302. In this case, the radiation impinging in the separating region 200 has an angle of incidence of 0°, such that even during irradiation on the side of the carrier material 104 that is provided with MEMS structures 102, it is possible without residues to remove material directly adjacent to the region of the carrier material 104 provided with MEMS structures 102.

If a predetermined breaking location 203 has been created in the separating region 200 (cf. FIGS. 3c, d), FIGS. 5a-c schematically depicts three possible ways of breaking up such a predetermined breaking location 203. In this case, the predetermined breaking location 203 has been created or formed in any desired manner, in general.

In accordance with FIG. 5a, the predetermined breaking location 203 is separated by a shear stress being introduced into the predetermined breaking location 203. Such a shear stress can be attained by opposing forces being applied to the carrier material 104 and the projection region 105. This is indicated by the arrows 90 in FIG. 5a, wherein the orientation of the arrows 90 can also be reversed.

As an alternative thereto, it is possible—as depicted schematically in FIG. 5a—for a predetermined breaking location 203 also to be broken up by a sufficient tensile stress being applied thereto, which is indicated by the arrows 91.

When breaking up the predetermined breaking location 203 in accordance with FIG. 5a, which is relevant for example to the embodiment variants of predetermined breaking locations 203 in which the material in the separating region 200 is partly weakened (cf. FIG. 3d), a temperature or a temperature gradient is introduced into the predetermined breaking location 203 (indicated by the heating element 92, although a cooling facility can also be provided). Different thermal expansion of weakening regions 205 vis-\grave{à}-vis the unchanged material can cause the predetermined breaking location to be broken up, for example.

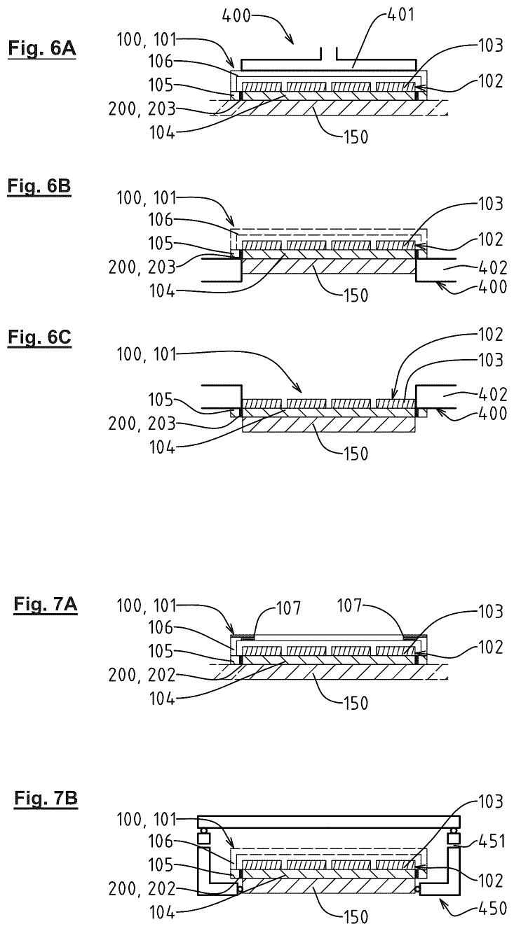

FIGS. 6a-c shows various variants or tools 400 in respect of how the shear stress already mentioned with reference to FIG. 5a can be introduced into a predetermined breaking location 203.

In FIG. 6a, it is assumed that the protective cover 106 is still fixedly connected to the projection regions 105, which for their part however—unlike the carrier material 104 in the region with MEMS structures 102—are not connected to the package substrate 150.

In this case, the tool 400 for breaking up the predetermined breaking location 203 is a suction die 401, which can be fixedly connected to the protective cover 106 by creating a vacuum between the suction die 401 and the protective cover. By pulling on the suction die 401 in a direction away from the package substrate 150 with simultaneous fixing thereof, a shear stress is generated in the predetermined breaking location 203 and can result in the breaking up thereof, whereupon the protective cover 106 and the projection regions 105 fixedly connected thereto can be removed from the MEMS chip 100 by the suction die 401. As an alternative to a suction die 401, a comparable tool 400 can also be fixedly connected to the protective cover 106 by adhesive bonding.

The tool 400 in FIG. 6b is suitable for example for an application in the case of MEMS chips 100 arranged on a package substrate 150 which does not extend beyond the region of the carrier material 104 provided with MEMS structures 102. The tool 400 is movable jaws 402, which, as shown in FIG. 6b, are positioned adjacent to the package substrate 150. Using vertical movement of the jaws 402, with the package substrate 150 kept fixed, the predetermined breaking locations 203 via which the projection regions 105 bearing against a jaw 402 are connected to the carrier material 104 can be broken up and the separated material can be removed. In this case, it is unimportant whether or not a protective cover 106 is connected to the projection regions 105 at the time of breaking up.

In FIG. 6c, the tool 400 from FIG. 6b is used again, although here the jaws 402 are positioned over the projection regions 105 in such a way that vertical movement of the jaws 402 in the direction of the package substrate 150 causes the projection regions 105 to be broken away correspondingly in the direction of the package substrate 150 at the respective predetermined breaking location 203. This can reduce the risk of collision between separated material and MEMS structure 102. However, in this embodiment variant, it is desirable for a protective cover 106 possibly present to be removed before the first predetermined breaking location 203 is broken up.

If a sacrificial material 202 is provided in the separating region 200 (cf. FIGS. 3b, c), which sacrificial material has to be removed for the purpose of creating a continuous gap 201 or a predetermined breaking location 203, this can be done e.g. via an etching process using etching medium, for example using etching gas.

In order to minimize the volume to be loaded with etching medium and to protect regions remote from the MEMS chip 100 against etching medium, inlet and outlet channels 107 may have been introduced, or may be introduced as desired, into a protective cover 106 still present at this point in time, through which channels an etching medium suitable for dissolving the sacrificial material 202 in the separating region 200 can be introduced and spent etching medium, etc., can also be removed again (cf. FIG. 7a). The detachment of protective cover 106 and projection regions 105 connected thereto after the sacrificial material 202 has been removed—regardless of whether a continuous gap 201 or a predetermined breaking location 203 is thereby created - can then take place e.g. in accordance with FIG. 6a.

FIG. 7b illustrates a variant in which the MEMS chip 100 with or without a protective cover 106 (therefore only illustrated in a dashed manner) is accommodated in a separate etching chamber 450 which encloses the MEMS chip 100 together with a package substrate 150 possibly present or—as illustrated—bears sealingly against the package substrate 150 and through the in- and outlets 451 of which etching medium is introduced. For example, it is possible in this way also to remove sacrificial material 202 accessible exclusively from the side facing away from the MEMS structures 102 in the separating regions 200. With respect to ultimately removing the projection regions 105 and/or the protective cover 106, optionally including breaking up a created predetermined breaking location, reference is made to the explanations above.

Even if projection regions 105 present can be removed by the above-described method for post-processing of MEMS chips 100, projection regions 105 can be reduced or even entirely avoided as early as during the production of corresponding MEMS chips 100, as a result of which the outlay for corresponding post-processing can also be reduced or completely obviated.

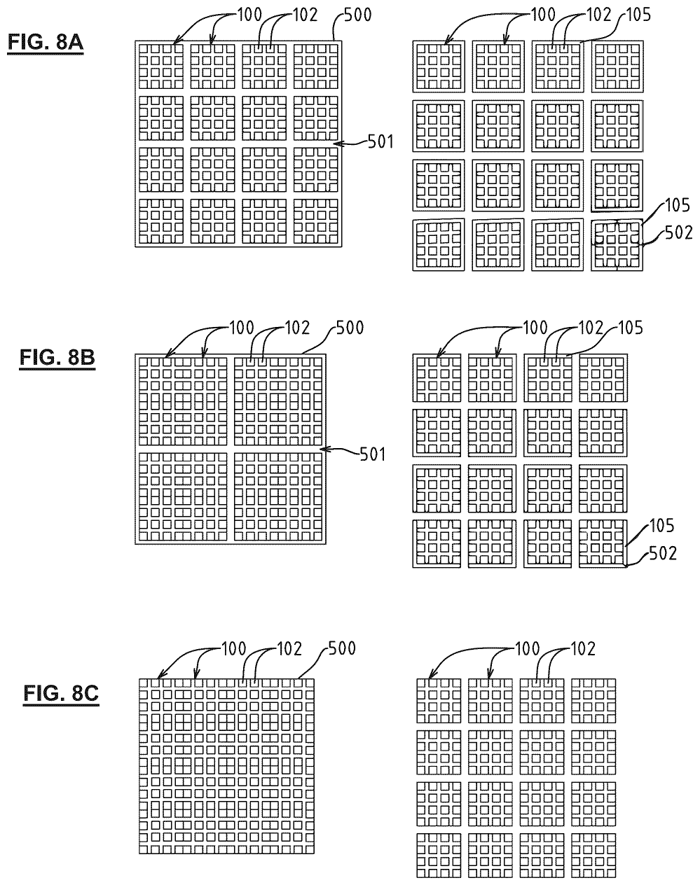

FIG. 8a schematically depicts typical production of MEMS chips 100: A plurality of groups of MEMS structures 102 are created on a wafer 500, each group later forming the MEMS structures 102 of an individual MEMS chip 100 (FIG. 8a, on the left). A respective clearance 501 is provided between the groups of MEMS structures 102 and—as known—can be used e.g. to connect a wafer having depressions (not illustrated) to the illustrated wafer 500 in order in this way to be able to create protective covers 106 for the MEMS chips 100 after the separation of the wafer 500 centrally through the clearances. The situation after the wafer 500 has been divided in such a way is illustrated in FIG. 8a, on the right. After the separation of the wafer 500, each MEMS chip 100 has a circumferential projection region 105, to which for example individual protective covers 106 can be secured (cf. FIGS. 2a-e).

In order to facilitate the removal of the projection regions 105, provision can be made, when dividing the wafer 500 or at a later point in time, for subdividing the projection regions 105 into individual sections by creating gaps or weakened regions 502, which sections can in general also be removed individually.

Especially if no protective cover 106 is used during the further handling of the MEMS chips 100, the MEMS structures 102 can be arranged in each case in pairs adjacently in one direction in a manner directly adjoining one another on the wafer 500 (FIG. 8b, on the left). After dividing the wafer 500, this then results in individual MEMS chips 100 in which the projection regions 105 are no longer present circumferentially (cf. FIG. 8a, on the right), but rather only on two of the four sides of each MEMS chip 100 (FIG. 8b, on the right). The outlay for post-processing, namely for removing the residual projection regions 105, accordingly decreases. Here, too, the projection regions 105 can be suitably subdivided into sections that can be removed individually.

As an alternative thereto, it is also possible, of course, to arrange the MEMS structures 102 completely without a clearance 501 (cf. FIGS. 8a, b) on the wafer 500 (cf. FIG. 8c, on the left), such that dividing the wafer 500 directly results in MEMS chips 100 without any projection regions 105 (FIG. 8c, on the right). In this case, dividing the wafer 500 can be realized by any known processes. For example, it is also possible to carry out the dividing by suitably removing carrier material in the course of the production of the MEMS structure. In this case, a process known from the production of MEMS structures for selective removal of material—e.g. an etching process—can be directly applied to the carrier material in order thus to achieve the dividing. Such an etching process can be provided as a separate step in the course of the production of the MEMS structures. However, it is also possible to effect “concomitant removal” in a method step provided for producing MEMS structures.

If MEMS chips 100 without any projection regions 105 are available—irrespective of whether they have been freed of originally present projection regions 105 by a post-processing method according to the disclosure (cf. FIGS. 2a to 7b) or have already been manufactured without projection regions 105 (cf. FIG. 8c)—they can be arranged, if this has not yet been done, at a very small distance from one another on a package substrate 150, as is depicted schematically in FIG. 9a.

For handling of the MEMS chips 100, a tool 600 is provided and enables the individual MEMS chips 100 to be gripped on two adjacent sides of the carrier material 104, such that the MEMS chips 100 can be arranged with the other two sides of the carrier material 104 directly adjacent to MEMS chips 100 already arranged on the package substrate 150. The tool 600 and its interplay with a MEMS chip 100 is shown in two plan views and two associated partial sectional views in FIG. 9b, wherein the right-hand illustrations each show the tool 600 in engagement, while the tool 600 is still separated from the MEMS chip 100 in the left-hand illustrations.

In order that the MEMS chips 100 can be gripped securely and precisely by the tool 600, the MEMS chips 100 have lateral depressions 108 in the region of the carrier material 104, into which depressions corresponding projections 601 on the tool 600, which for the rest is configured like tongs, can engage in a positively locking manner.

In addition to the two depressions 108, from which the orientation of the MEMS structures of the MEMS chip vis-à-vis the carrier material also be read.

If depressions for engagement of a handling tool 600 are provided only on two adjacent sides of the carrier material, but at least one side of the carrier material is depression-free, the orientation of the MEMS structures 102 of the MEMS chip 100 vis-à-vis the carrier material 104 can be read from the arrangement of the depressions, as a result of which the correct alignment of each MEMS chip 100 can be ensured during the integration thereof. On the carrier material 100, provision can be made of even further depressions in a form and arrangement comparable to a barcode as marking 109, in which batch or serial numbers of the respective MEMS chip 100 are stored.

The depressions 108 and also the marking 109 can be integrated into the carrier material 104 during the production of the MEMS chip 100. For example, the regions in question, which are regularly internal regions at least temporarily, can firstly be filled with sacrificial material corresponding to a sacrificial material 202 in the separating region 200, which material can be removed in the course of the removal of the sacrificial material 202 in the separating region 200.

What is claimed is:

1. A method of post-processing of MEMS chips comprising MEMS structures, a carrier material supported by the MEMs structures and a projection region protruding laterally beyond a region defined with MEMS structures, the projection region comprising a projection material, the method comprising:
removing the projection region by separating the projecting material from the carrier material.

2. The method of claim 1, wherein removing the projection region comprises creating a continuous gap between the projection region and the carrier material.

3. The method of claim 2, wherein creating the continuous gap comprises removing a sacrificial material in a region of the continuous gap, the sacrificial material being different from the projecting material.

4. The method of claim 3, wherein the sacrificial material is removed by an etching process.

5. The method of claim 2, wherein creating the continuous gap comprises removing material without residues.

6. The method of claim 1, wherein removing the projection region comprises creating a predetermined breaking location between the projection region and the carrier material, and subsequently breaking up the predetermined breaking location.

7. The method of claim 6, wherein creating the predetermined breaking location comprises removing a sacrificial material in a region of the breaking location, the sacrificial material being different from the projecting material.

8. The method of claim 7, wherein the sacrificial material is removed by an etching process.

9. The method of claim 6, wherein creating the predetermined breaking location comprises removing material without residues.

10. The method of claim 6, wherein creating the predetermined breaking location comprises weakening material in a region of the breaking location in a targeted manner.

11. The method of claim 10, wherein high energy radiation is used to weaken the material in the region of the breaking location.

12. The method of claim 10, further comprising breaking up the breaking location by introducing shear stress and/or tensile stress.

13. The method of claim 10, further comprising breaking up the breaking location by changing a temperature and/or by introducing a temperature gradient.

14. The method as claimed in any of the preceding claims, characterized in that
at least one projection region is configured for attaching a protective cover for the MEMS chip and the protective cover is removed at the same time as the projection region.

15. The method of claim 1, wherein the MEMS chip comprises a MEMS mirror array.

16. The method of claim 1, further comprising:
after removing the projecting material, providing lateral depressions in the carrier material; and
handling the MEMS chips using a tool engaging in the lateral depressions.

17. The method of claim 16, wherein the depressions lateral comprise first and second lateral depressions, the first lateral depression being in a first side of the carrier material, and the second lateral depression in a second side of the carrier material adjacent the first side of the carrier material.

18. A method for handling of MEMS chips comprising MEMs structures and a carrier supporting the MEMs structures, the MEMS chips being devoid of regions projecting beyond the MEMS structures, the method comprising:
providing lateral depressions in the carrier material; and
handling the MEMS chips using a tool engaging in the lateral depressions.

19. The method of claim 18, wherein the depressions lateral comprise first and second lateral depressions, the first lateral depression being in a first side of the carrier material, and the second lateral depression in a second side of the carrier material adjacent the first side of the carrier material.

20. The method of claim 18, wherein the carrier comprise laterally arranged markings.
